(19) United States
(12) Patent Application Publication
(10) Pub. No.: US 2026/0090019 A1
(43) Pub. Date: Mar. 26, 2026

(54) THIN FILM TRANSISTOR, PREPARATION METHOD THEREOF, AND DISPLAY PANEL

(71) Applicant: Yungu (Gu’an) Technology Co., Ltd., Langfang (CN)

(72) Inventors: Fa-Hsyang CHEN, Langfang (CN); Yinghai MA, Langfang (CN); Bin GUO, Langfang (CN); Xue LIU, Langfang (CN); Qidi LIU, Langfang (CN); Mengsen WANG, Langfang (CN)

(73) Assignee: Yungu (Gu’an) Technology Co., Ltd., Langfang (CN)

(21) Appl. No.: 19/409,795

(22) Filed: Dec. 5, 2025

Related U.S. Application Data
(63) Continuation of application No. PCT/CN2023/134317, filed on Nov. 27, 2023.

(30) Foreign Application Priority Data
Jun. 29, 2023 (CN) 202310790822.3

(51) Int. Cl. H10D 30/67; H10D 30/01; H10D 86/60

(52) U.S. Cl. CPC H10D 30/6731; H10D 30/0312; H10D 30/0314; H10D 30/6756; H10D 86/60; H10D 30/0316; H10D 30/6732; H10D 30/6734

(57) ABSTRACT

The present disclosure provides a thin film transistor, a preparation method thereof, and a display panel. The thin film transistor includes an active layer and a first gate electrode located on a base substrate, the active layer includes a first film layer and a second film layer stacked on the base substrate, the second film layer is located between the first film layer and the first gate electrode, the first film layer includes oxygen element, the second film layer includes crystalline oxide, and the first film layer and the second film layer are formed via synchronous annealing. This approach not only prevents the thin film transistor channel from conducting due to insufficient oxygen content in the second film layer but also avoids issues such as etching residues caused by difficulties in etching the second film layer due to excessive oxygen content during the etching process.

### CROSS-REFERENCE TO RELATED APPLICATIONS

The present application is a continuation application of International Application No. PCT/CN2023/134317, filed on Nov. 27, 2023, which claims priority to Chinese Patent Application No. 202310790822.3, filed on Jun. 29, 2023. All of the aforementioned patent applications are hereby incorporated by reference in their entireties.

### FIELD

The present disclosure relates to the field of display technologies, and in particular, to a thin film transistor, a preparation method thereof, and a display panel.

### BACKGROUND

With the development of information technology, electronic display products are being used at an increasingly higher frequency in daily life. Thin film transistors serves as primary switching elements in the driving circuits of the electronic display products. However, constrained by its own structural design and formation process, an active layer in current thin film transistors struggles to simultaneously guarantee good film formation quality, high mobility, and high stability, thereby limiting the further improvement of thin film transistor performance.

### SUMMARY

A first aspect of the present disclosure provides a thin film transistor. The thin film transistor includes a base substrate, an active layer and a first gate electrode, the active layer and the first gate electrode are located on the base substrate, the active layer includes a first film layer and a second film layer stacked on the base substrate, the second film layer is located between the first film layer and the first gate electrode, the first film layer includes oxygen element, and the second film layer includes crystalline oxide. The first film layer and the second film layer are formed via synchronous annealing.

In the above solution, the annealing enables a portion of the oxygen element originally present in the first film layer to supplement the second film layer. Therefore, the second film layer does not need to be prepared in a high-oxygen environment (for example, high oxygen partial pressure). This approach not only prevents the thin film transistor channel from conducting due to insufficient oxygen content in the second film layer but also avoids issues such as etching residues caused by difficulties in etching the second film layer due to excessive oxygen content during the etching process.

A second aspect of the present disclosure provides a display panel, and the display panel may include the thin film transistor according to the first aspect.

A third aspect of the present disclosure provides a preparation method of a thin film transistor. The preparation method includes: providing a base substrate; forming a first pattern layer including oxygen element on the base substrate, depositing a semiconductor film on the base substrate, and patterning the semiconductor film to form a second pattern layer, where the first pattern layer and the second pattern layer are stacked on the base substrate and in contact with each other; performing annealing on the first pattern layer and the second pattern layer, so that the oxygen element in the first pattern layer diffuses into the second pattern layer, where the first pattern layer after annealing forms a first film layer, the second pattern layer after annealing forms a second film layer; and depositing a conductive material thin film and patterning the conductive material thin film to form a first gate electrode, where the second film layer is formed between the first film layer and the first gate electrode.

### BRIEF DESCRIPTION OF THE DRAWINGS

FIG. 1 is a cross-sectional view of a thin film transistor provided by an embodiment of the present disclosure.

FIG. 2 is a cross-sectional view of another thin film transistor provided by an embodiment of the present disclosure.

FIG. 3 is a cross-sectional view of another thin film transistor provided by an embodiment of the present disclosure.

FIG. 4 is a cross-sectional view of another thin film transistor provided by an embodiment of the present disclosure.

FIG. 5 is a cross-sectional view of another thin film transistor provided by an embodiment of the present disclosure.

FIG. 6 is a cross-sectional view of another thin film transistor provided by an embodiment of the present disclosure.

FIG. 7 is a cross-sectional view of another thin film transistor provided by an embodiment of the present disclosure.

FIG. 8 is a cross-sectional view of an array substrate provided by an embodiment of the present disclosure.

FIG. 9 is a planar schematic structural diagram of a display panel provided by an embodiment of the present disclosure.

FIG. 10 is a cross-sectional view of the display panel shown in FIG. 9 taken along the line M-N.

FIG. 11 is a flowchart of a preparation method of a thin film transistor provided by an embodiment of the present disclosure.

FIGS. 12 to 17 are process diagrams of a preparation method of a thin film transistor provided by an embodiment of the present disclosure.

### DETAILED DESCRIPTION OF THE EMBODIMENTS

In the preparation process of a thin film transistor, crystalline oxide with high mobility and high stability is selected as channel material. The reasons are as follows:: crystalline oxide materials possess a relatively high dielectric constant, thereby increasing capacitance of a transistor and improving performance of the thin film transistor; the crystalline oxide materials possess a relatively high carrier mobility, which may improve response speed and output power of the thin film transistor; in addition, the crystalline oxide materials possess relatively high chemical stability and thermal stability, ensuring long-term stability and reliability of the thin film transistor; furthermore, the crystalline oxide materials can be prepared through modern manufacturing processes such as chemical vapor deposition, thereby achieving high-precision and high-quality production.

However, in current processes, to ensure high mobility and high stability of the crystalline oxide, the crystalline oxide is formed in a high oxygen partial pressure environment. However, a film layer formed in this manner is difficult to etch (pattern), easily causing residues and leading to device defects; if the film layer is formed in a low oxygen partial pressure environment, the channel of the thin film transistor tends to conduct, thereby making the thin film transistor prone to leakage current.

Embodiments of the present disclosure provide a thin film transistor, a preparation method thereof, and a display panel, to at least solve the above technical problems. The thin film transistor includes a base substrate, an active layer and a first gate electrode, the active layer and the first gate electrode are located on the base substrate, the active layer includes a first film layer and a second film layer stacked on the base substrate, the second film layer is located between the first film layer and the first gate electrode, the first film layer includes oxygen element, and the second film layer includes crystalline oxide. In this design, the active layer is subjected to an annealing treatment. During annealing, the oxygen element originally present in the first film layer is supplemented into the second film layer. Therefore, the second film layer does not need to be prepared in a high oxygen environment (for example, high oxygen partial pressure). This approach not only prevents the thin film transistor channel from conducting due to insufficient oxygen content in the second film layer but also avoids issues such as etching residues caused by difficulties in etching the second film layer due to excessive oxygen content during the etching process.

The structures involved in the thin film transistor, the preparation method, and the display panel according to at least one embodiment of the present disclosure will be described below with reference to the drawings. In these embodiments, a spatial rectangular coordinate system is established by taking a plane of the base substrate in the thin film transistor (for example, a display surface of the display panel) as a reference, in order to describe the positions of various structures in the thin film transistor and the display panel. In the spatial rectangular coordinate system, the X-axis and the Y-axis are parallel to the base substrate, and the Z-axis is perpendicular to the base substrate.

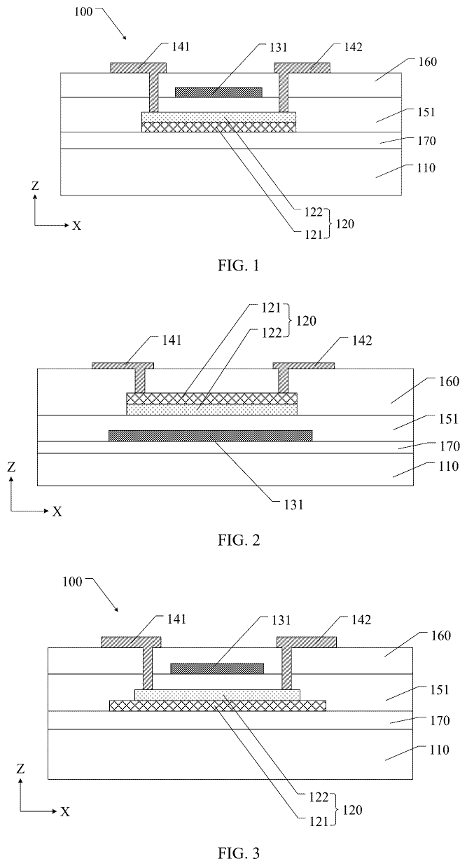

As shown in FIG. 1, a thin film transistor 100 includes an active layer 120, a first gate electrode 131, a source electrode 141, and a drain electrode 142. The source electrode 141 and the drain electrode 142 are connected to the active layer 120, and the first gate electrode 131 is spaced apart from the active layer 120. The base substrate 110 is configured to support the active layer 120, the first gate electrode 131, the source electrode 141, and the drain electrode 142. By controlling a voltage on the first gate electrode 131, a voltage fluctuation is induced in the active layer 120 to generate carriers, thereby forming a current channel. Thus, a switching and degree of opening of the thin film transistor 100 are controlled.

The active layer 120 includes a first film layer 121 and a second film layer 122 stacked together. The second film layer 122 includes crystalline oxide (a semiconductor layer), the first film layer 121 includes oxygen element. The first film layer 121 and the second film layer 122 are formed via synchronous annealing. Thus, the oxygen element in the first film layer 121 diffuses into the second film layer 122 during annealing, causing oxygen element content in the second film layer 122 to reach an expected level, so that the second film layer 122 possesses high mobility and high stability. Accordingly, the situation reduces the oxygen content that the second film layer 122 is required to include before annealing. Therefore, before annealing, during the preparation of the second film layer 122, the lower oxygen element content makes etching easier, thereby preventing residues during the etching of the second film layer 122.

In the embodiments of the present disclosure, the second film layer 122 serves as the main film layer constituting the channel in the active layer 120. In a case where the second film layer 122 is located between the first film layer 121 and the first gate electrode 131, a distance between the second film layer 122 and the first gate electrode 131 is reduced, thereby improving the sensitivity of the thin film transistor during driving.

For example, in at least one embodiment of the present disclosure, as shown in FIG. 1, the thin film transistor 100 also includes a first gate insulator layer 151 and an interlayer dielectric layer 160 to define the various structures in the thin film transistor 100. For example, the first gate insulator layer 151 is located between the first gate electrode 131 and the active layer 120 to separate the first gate electrode 131 and the active layer 120. The interlayer dielectric layer 160 is located between a source drain electrode layer (including the source electrode 141 and the drain electrode 142) and the active layer 120 to separate the source drain electrode layer and the active layer 120.

For example, in at least one embodiment of the present disclosure, as shown in FIG. 1, the thin film transistor 100 may further include a buffer layer 170, and the buffer layer 170 is located between the base substrate 110 and the active layer 120. The buffer layer 170 blocks harmful ions invading from the base substrate 110 into the active layer 120.

It should be noted that in the embodiments of the present disclosure, as long as the first film layer provides the oxygen element to the second film layer during annealing, there is no limitation on the specific material of the first film layer. Hereinafter,, exemplary explanations are provided for different material selections of the first film layer and the structure of the thin film transistor under the corresponding selections.

In some embodiments of the present disclosure, as shown in FIG. 1, the first film layer 121 may be configured as a semiconductor layer, and the first film layer is a film layer formed by amorphous oxide via annealing. That is, the first film layer 121 is the semiconductor layer formed by amorphous oxide material.

During annealing, chemical bonds within molecules of the amorphous oxide become unstable, thereby leading to the release of oxygen ion; in addition, high temperature increases an active site on an oxide surface, thereby making it easier to react with other molecules, and thereby resulting in the loss of the oxygen ion.

It should be noted that the mobility of the first film layer composed of the amorphous oxide is lower than the mobility of the second film layer composed of the crystalline oxide. Therefore, the second film layer is used to form the channel, that is, when the thin film transistor is operational (for example, turned on), a two-dimensional electron gas (carriers) is formed in the second film layer. For example, the two-dimensional electron gas may gather on a surface of the second film layer facing a gate electrode (for example, the first gate electrode).

For example, as shown in FIG. 1, when the first film layer 121 is the semiconductor layer, the first film layer 121 and the second film layer 122 may be formed in the same patterning process to reduce the preparation process flow of the active layer 120. In this case, the patterns of the first film layer 121 and the second film layer 122 roughly coincide, that is, an orthographic projection, located on the base substrate 110, of the first film layer 121 coincides with an orthographic projection, located on the base substrate 110, of the second film layer 122.

In the embodiments of the present disclosure, the two objects with “coinciding” projections have the same planar shape and equal area. Moreover, along a direction of the projection (with the direction of the orthographic projection is the Z-axis direction), the two objects are positioned directly opposite each other.

It should be noted that in the embodiments of the present disclosure, in a case where the first film layer is the semiconductor layer and the thin film transistor includes only one gate electrode (the first gate electrode), the thin film transistor may be configured as a top-gate thin film transistor, or a bottom-gate thin film transistor, as detailed below.

For example, in some embodiments of the present disclosure, as shown in FIG. 1, in a case where the first film layer 121 is the semiconductor layer, the first film layer 121 is located between the second film layer 122 and the base substrate 110, that is, the thin film transistor 100 is the top-gate thin film transistor.

For example, in other embodiments of the present disclosure, as shown in FIG. 2, in a case where the first film layer 121 is the semiconductor layer, the second film layer 122 is located between the first film layer 121 and the base substrate 110, that is, the thin film transistor 100 is the bottom-gate thin film transistor.

For example, as shown in FIG. 2, in a case where the thin film transistor 100 is the bottom-gate thin film transistor, an orthographic projection, located on the base substrate 110, of the active layer 120 is located within an orthographic projection, located on the base substrate 110, of the first gate electrode 131, thus preventing the arrangement of the first gate electrode 131 from adversely affecting the flatness of the active layer 120; in addition, the first gate electrode 131 may block light transmitted from a side of the base substrate 110, thereby reducing an issue of photogenerated carriers in the active layer 120; furthermore, the first gate electrode 131 may block harmful ions invading from the base substrate 110 to the active layer 120.

In a case where the first film layer is composed of the amorphous oxide, both the first film layer and the second film layer are formed in a certain oxygen partial pressure environment (for example, physical vapor deposition, physical chemical vapor deposition, and so on), therefore, by controlling the oxygen partial pressure environment during the deposition of the first film layer and the second film layer, the oxygen content of the first film layer and the second film layer in an initial state of a film formation may be controlled, and the amount of the oxygen element that may diffuse out from the first film layer under annealing conditions may be controlled.

For example, in some embodiments of the present disclosure, in a case where the first film layer includes the amorphous oxide, a film formation oxygen partial pressure during annealing for forming the amorphous oxide film layer of the first film layer is greater than a film formation oxygen partial pressure during annealing for forming the semiconductor film layer of the second film layer. Thus, the first film layer formed under high oxygen partial pressure conditions includes more easily separable the oxygen element, which is prone to lose the oxygen element during annealing, thereby allowing the oxygen element therein to diffuse into the second film layer.

For example, the film formation oxygen partial pressure of the amorphous oxide film layer that forms the first film layer via annealing is 30% to 90%, and the film formation oxygen partial pressure of the semiconductor film layer (for example, a second pattern layer described below) that forms the second film layer via annealing is 10% to 60%.

“Oxygen partial pressure” refers to a partial pressure of oxygen in a gas mixture under specific temperature and environment. For example, in some embodiments of the present disclosure, a mixed gas used for the oxygen partial pressure consists of oxygen and inert gas (for example, argon), and the oxygen partial pressure represents a ratio of a pressure provided by the oxygen to a pressure of the mixed gas.

In a case where the material of the first film layer includes the amorphous oxide, the specific type of the amorphous oxide is not limited and is determined according to actual process requirements. For example, the material of the first film layer includes at least one of In, Ga, or Zn. For example, the first film layer is a quaternary material, that is, the first film layer includes four elemental materials. Exemplarily, the material of the first film layer includes IGZO. For example, optionally, the material of the first film layer is further doped with at least one of Fe, Cu, Al, Zr, or Ti.

In a case where the material of the second film layer includes the crystalline oxide, the specific type of the crystalline oxide is not limited and is determined according to actual process requirements. For example, the material of the second film layer includes at least one of In, Sn, Ga, or Zn. For example, the second film layer is a ternary material, that is, the second film layer includes three elemental materials. Exemplarily, the material of the second film layer includes ITO, IZO, or IGO. Optionally, the material of the second film layer is further doped with at least one of Fe, Cu, Al, Zr, or Ti. A material layer used to prepare the second film layer is an amorphous oxide layer or a crystalline oxide layer before annealing.

It should be noted that in the embodiments of the present disclosure, the thickness range of both the first film layer and the second film layer is 40 to 250 angstroms, such as 150 angstroms, 200 angstroms, and so on. The specific thickness is designed according to actual process needs and is not limited to the above range.

In some other embodiments of the present disclosure, as shown in FIG. 3, the first film layer 121 is a layer formed by an oxygen-rich oxide layer via annealing. The oxygen element in the oxygen-rich oxide is prone to separation to form the oxygen ion, which diffuse to the surroundings.

It should be noted that in the embodiments of the present disclosure, in a case where the first film layer is the oxygen-rich oxide before annealing and the thin film transistor includes only one gate electrode (the first gate electrode), the thin film transistor may be configured as the top-gate thin film transistor or the bottom-gate thin film transistor, as detailed below.

For example, in some embodiments of the present disclosure, as shown in FIG. 3, in a case where the first film layer 121 is the oxygen-rich oxide layer before annealing, the first film layer 121 is located between the second film layer 122 and the base substrate 110, and the orthographic projection, located on the base substrate 110, of the second film layer 122 is located within the orthographic projection, located on the base substrate 110, of the first film layer 121. That is, the thin film transistor 100 is the top-gate thin film transistor.

For example, in some other embodiments of the present disclosure, when the first film layer is the oxygen-rich oxide layer before annealing, the second film layer is located between the first film layer and the base substrate. That is, the thin film transistor is the bottom-gate thin film transistor. For example, in this case, the first film layer only covers the channel portion of the second film layer (overlapping with the first gate electrode), so that the source electrode and the drain electrode are in direct contact with the second film layer; or, the first film layer completely covers the second film layer, but with via holes formed in the first film layer, and the source electrode and the drain electrode are connected to the second film layer through the via holes.

“Oxygen-rich oxide” refers to the oxide with a higher content of the oxygen element in the compound. These compounds usually contain a large number of oxygen atoms, and exhibit relatively active chemical properties, thereby making them prone to lose oxygen during the annealing process. In the embodiments of the present disclosure, the material of the oxygen-rich oxide is not limited and is selected according to actual process needs. For example, the oxygen-rich oxide includes at least one of iron oxide, copper oxide, aluminum oxide, alumina, zirconia, or titanium oxide, and so on.

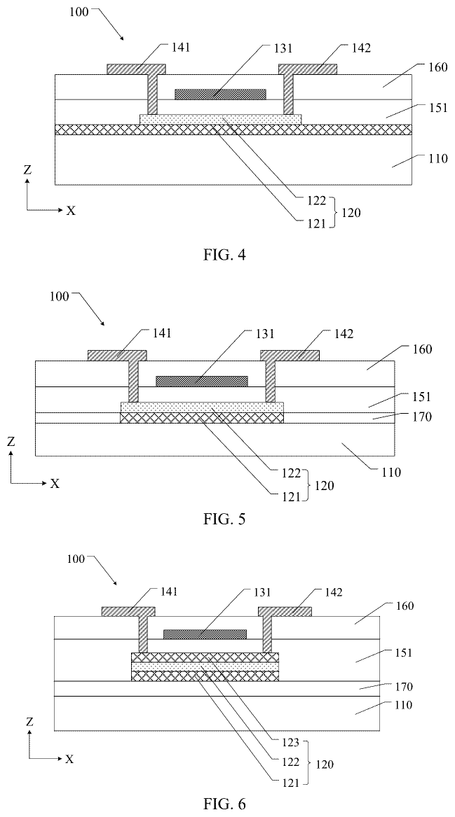

In some other embodiments of the present disclosure, as shown in FIG. 4, the first film layer 121 is configured as a base material layer including oxygen ion. The base material layer covers the base substrate 110, and at least a partial region of the base material layer includes the oxygen ion. The region of the base material layer including the oxygen ion serves as the first film layer 121. That is, the orthographic projection, located on the base substrate 110, of the second film layer 122 at least partially overlaps with an orthographic projection, located on the base substrate 110, of the region including the oxygen ion in the base material layer. For example, the oxygen ion can be injected into the base material layer through ion implantation, so that the region of the base material layer overlapping with the second film layer 122 has the oxygen ion.

For example, in some embodiments, as shown in FIG. 4, in a case where the first film layer 121 is configured as the base material layer including the oxygen ion, the entire region of the base material layer includes the oxygen ion. For example, when fabricating the thin film transistor, a full-layer base material layer is deposited on the base substrate, then the oxygen ion is included in the base material layer, and then the second film layer 122 is prepared. In this case, the first film layer 121 can be considered as a full-surface layer covering the base substrate 110.

For example, in some embodiments, as shown in FIG. 5, in a case where the first film layer 121 is configured as the base material layer including the oxygen ion, the region of the base material layer overlapping with the second film layer 122 includes the oxygen ion, and the portion of the base material layer including the oxygen ion is the first film layer 121. For example, when fabricating the thin film transistor, the full-layer base material layer is deposited on the base substrate, then the oxygen ion is included in a partial region of the base material layer, and then the second film layer 122 is prepared, where the region including the oxygen ion roughly overlaps with the second film layer 122. In this case, the first film layer 121 overlaps with the second film layer 122; in addition, during annealing, the oxygen ion included in the base material layer may all be used to diffuse into the second film layer 122 without invading and floating in other film layers, thereby avoiding any adverse effects on the performance of the thin film transistor or other devices (such as components in a display panel).

For example, as shown in FIG. 5, in a case where the first film layer 121 is configured as the base material layer including the oxygen ion, the first film layer 121 is located between the second film layer 122 and the base substrate 110. That is, the thin film transistor is at least a top-gate type thin film transistor (for example, it may be further designed as a dual-gate type thin film transistor).

For example, as shown in FIG. 5, in a case where the first film layer 121 is configured as the base material layer including the oxygen ion, the base material layer is designed as an inorganic layer. The inorganic layer has high density, improves the surface defects of the base substrate 110 and blocks harmful ions from the base substrate 110. In this case, the base material layer actually serves as the buffer layer 170. That is, in this design, the first film layer 121 and the buffer layer 170 are integrated together to simplify module design.

For example, when the base material layer serves as the buffer layer, the material of the base material layer is silicon nitride, silicon oxide, or silicon oxynitride, and so on.

In at least one embodiment of the present disclosure, as shown in FIG. 6, the active layer 120 may further include a third film layer 123, the third film layer 123 is located between the second film layer 122 and the first gate electrode 131, and the third film layer 123 is an film layer formed by annealing the amorphous oxide film layer. In this way, during annealing, the oxygen element in the first film layer 121 and the third film layer 123, which are located on both sides of the second film layer 122, can simultaneously diffuse into the second film layer 122, thereby increasing the efficiency of the oxygen element entering the second film layer 122; in addition, the first film layer 121 and the third film layer 123 can act as barriers on both sides of the second film layer 122, thereby reducing the risk of harmful ions invading the second film layer 122.

It should be noted that a mobility of the third film layer composed of the amorphous oxide is lower than the mobility of the second film layer composed of the crystalline oxide. Therefore, the second film layer is still used to constitute the channel.

For example, in some embodiments of the present disclosure, as shown in FIG. 6, in a case where the third film layer is a semiconductor material (the amorphous oxide film layer), the third film layer 123 and the second film layer 122 are fabricated in the same patterning process to reduce the preparation process flow of the active layer 120. In this case, an orthographic projection, located on the base substrate 110, of the third film layer 123 coincides with the orthographic projection, located on the base substrate 110, of the second film layer 122. For example, the orthographic projections of the first film layer 121, the second film layer 122, and the third film layer 123 on the base substrate 110 all coincide. That is, the first film layer 121, the second film layer 122, and the third film layer 123 are formed in the same patterning process. In this way, contamination (such as ion intrusion) of the second film layer 122 due to contact with other materials (for example, photoresist) may be avoided.

It should be noted that both ends of the second film layer need to be doped (for example, heavy doping) to achieve conductivity, thereby facilitating the electrical connection between the active layer and the source electrode and the drain electrode. In this case, the configurations of the first film layer and the third film layer should ensure no adverse impact on the doping process of the second film layer.

For example, in at least one embodiment of the present disclosure, as shown in FIG. 6, in a case where the first film layer 121, the second film layer 122, and the third film layer 123 are sequentially stacked on the base substrate 110, a film formation oxygen partial pressure during annealing the amorphous oxide film layer to form the third film layer 123 is greater than a film formation oxygen partial pressure during annealing the semiconductor film layer to form the second film layer 122, and less than a film formation oxygen partial pressure during annealing the amorphous oxide film layer to form the first film layer 121. In this way, it may be avoided that excessive oxygen content in the third film layer 123 makes it difficult to perform heavy doping on both ends of the second film layer 122.

For example, the film formation oxygen partial pressure during annealing the amorphous oxide film layer to form the third film layer is 15% to 85%.

In a case where the material of the third film layer includes the amorphous oxide, the specific type of the amorphous oxide is not limited and may be determined according to actual process requirements. For example, the material of the third film layer may include at least one of In, Ga, or Zn. For example, the third film layer may be a quaternary material, and exemplarily, the material of the third film layer may include IGZO. For example, optionally, the material of the third film layer may also be doped with at least one of Fe, Cu, Al, Zr, or Ti.

It should be noted that in the embodiments of the present disclosure, the thickness range of the third film layer may be 40 to 250 angstroms, such as 150 angstroms, 200 angstroms, and so on. The specific thickness of the third film layer may be designed according to actual process needs and is not limited to the above range.

It should be noted that in the embodiments of the present disclosure, the active layer may also be configured as a stack composed of four or more film layers, and the properties of the additionally provided film layers may be similar to those of the first film layer and the third film layer, so that more oxygen elements may diffuse into the second film layer. For example, these additionally added film layers may be located between the second film layer and the base substrate to avoid hindering the doping process of the second film layer.

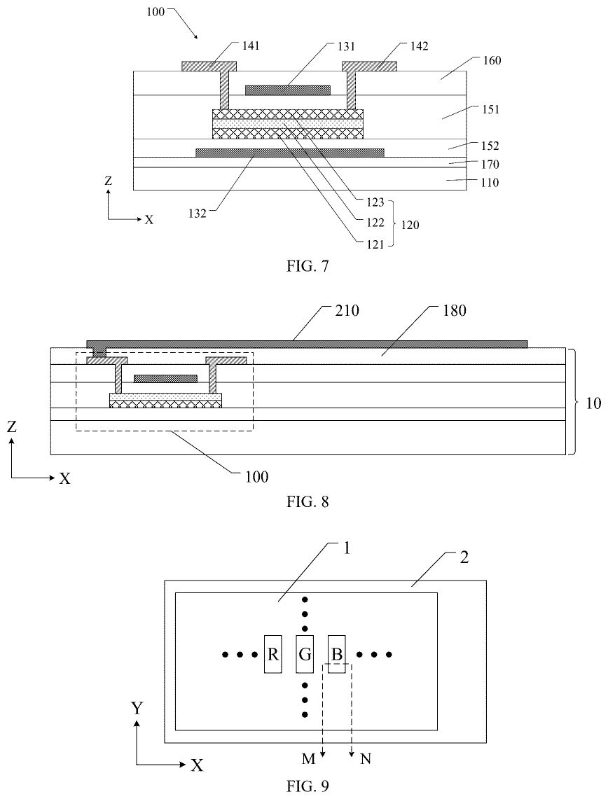

In at least one embodiment of the present disclosure, as shown in FIG. 7, the thin film transistor 100 may be designed as a dual-gate type thin film transistor to improve the response speed of the thin film transistor. For example, the thin film transistor 100 may include a second gate electrode 132, and the second gate electrode 132 is located on a side of the active layer 120 away from the first gate electrode 131.

It should be noted that for the first gate electrode and the second gate electrode, the area of the one located between the active layer and the base substrate should be larger than the area of active layer to block the active layer and ensure the flatness of the active layer. Exemplarily, as shown in FIG. 7, the second gate electrode 132 is located between the active layer 120 and the base substrate 110, and an orthographic projection, located on the base substrate 110, of the active layer 120 is within an orthographic projection, located on the base substrate 110, of the second gate electrode 132.

For example, as shown in FIG. 7, in a case where the second gate electrode 132 is provided, the thin film transistor 100 may also include a second gate insulator layer 152, where the second gate insulator layer 152 is located between the active layer 120 and the second gate electrode 132.

It should be noted that in the embodiments of the present disclosure, whether two gate electrodes are provided in the thin film transistor is not limited by the number of film layers of the active layer and may be selected according to actual needs. For example, in a case where the second gate electrode is not provided, the second gate electrode may still be provided on the side of the active layer away from the first gate electrode to improve the response speed of the thin film transistor.

At least one embodiment of the present disclosure provides an array substrate, as shown in FIG. 8, the array substrate may include a driving circuit layer 10, the driving circuit layer includes a plurality of pixel driving circuits, each pixel driving circuit includes a plurality of thin film transistors 100, and at least one of these thin film transistor is the thin film transistor described in the above embodiment.

For example, the pixel driving circuit may include a plurality of transistors TFT (thin film transistors), capacitors, and so on, and may be formed in various forms such as 2T1C (that is, two transistors (TFT) and one capacitor (C)), 3T1C, 7T1C, and so on. The pixel driving circuit is connected to a light emitting device (see the light emitting device 200 in the following embodiments) to control the switching state and luminous brightness of the light emitting device.

For example, in at least one embodiment of the present disclosure, as shown in FIG. 8, the array substrate may further include a planarization layer 180 and an anode 210 located on the planarization layer 180. Via holes are provided within the planarization layer 180, the pixel driving circuit is arranged corresponding to the anode 210, and the source electrode or the drain electrode of one of the thin-film transistors in the pixel driving circuit is connected to the corresponding anode 210 through the via holes.

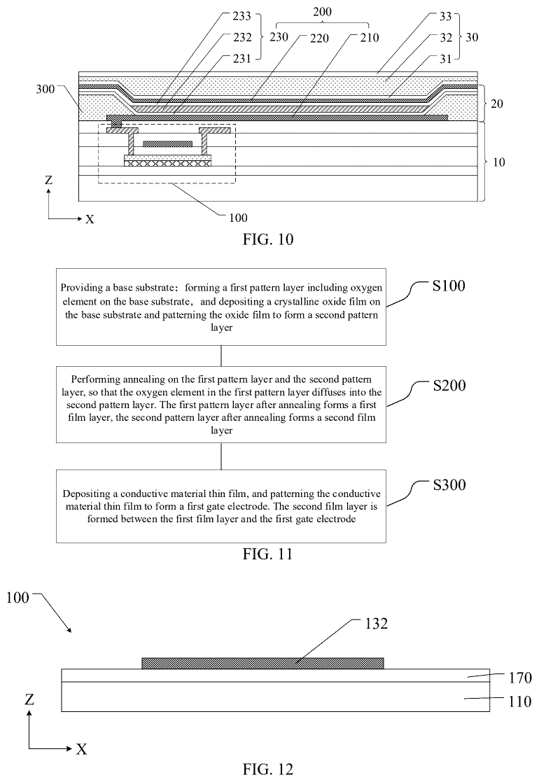

At least one embodiment of the present disclosure provides a display panel, as shown in FIGS. 9 to 10, the display panel includes a display function layer 20 and the array substrate 10 described in the above embodiments. The display panel may be divided into a display region 1 and a frame region 2 located on at least one side of the display region 1. A plurality of sub-pixels R, G, and B are arranged within the display region 1. The display functional layer 20 is located on the array substrate 10 and includes a plurality of light emitting devices 200. The plurality of light emitting devices 200 are the physical light-emitting structure of the sub-pixels R, G, B. For example, the light emitting devices 200 respectively located in the sub-pixels R, G, B are respectively designed to emit red light (R), green light (G), and blue light (B). For example, the light emitting device 200 is connected to the pixel driving circuit within the array substrate 10.

The light emitting device 200 may include an anode 210, a emitting functional layer 230, and a cathode 220 sequentially stacked on the array substrate. The emitting functional layer 230 may include a first common layer 231, a emitting layer 232, and a second common layer 233 sequentially stacked on the anode 210. For example, the first common layer 231 may include a hole injection layer, a hole transport layer, and may further include an electron blocking layer, and so on. For example, the second common layer 233 may include an electron injection layer, an electron transport layer, and may further include a hole blocking layer, and so on.

For example, as shown in FIG. 10, the display panel may also include a pixel definition layer 300, which includes a plurality of openings to define the position of the light emitting device. For example, the emitting layer of each light emitting device 200 is located in the opening.

For example, as shown in FIG. 10, the display panel may also include an encapsulation layer 30 to cover the display functional layer 20, so as to protect the light emitting device 200. For example, the encapsulation layer 30 may include a first inorganic encapsulation layer 31, an organic encapsulation layer 32, and a second inorganic encapsulation layer 33, which are sequentially stacked on the display functional layer 20.

For example, in the embodiments of the present disclosure, the display panel may also include functional structures such as a touch functional layer, a polarizer, a lens layer, and a cover plate located on a display side (for example, on the encapsulation layer) of the display panel.

For example, in the embodiments of the present disclosure, the display panel may be any product or component with a display function, such as a TV, a digital camera, a mobile phone, a watch, a tablet computer, a laptop computer, or a navigator, and so on.

At least one embodiment of the present disclosure provides a preparation method of a thin film transistor mentioned in the above embodiments. As shown in FIG. 11, the preparation method may include the following steps S100 to S300.

S100, providing a base substrate; forming a first pattern layer including oxygen element on the base substrate, depositing a semiconductor film on the base substrate and patterning the semiconductor film to form a second pattern layer. The first pattern layer and the second pattern layer are stacked on the base substrate and in contact with each other.

S200, performing annealing on the first pattern layer and the second pattern layer, so that the oxygen element in the first pattern layer diffuses into the second pattern layer. The first pattern layer after annealing forms a first film layer. The second pattern layer after annealing forms a second film layer, and the second film layer includes crystalline oxide.

It should be noted that whether the semiconductor material crystallizes during annealing depends on the structure and chemical composition of the material. That is, for amorphous semiconductor materials, some amorphous semiconductor materials do not crystallize during annealing, while other amorphous semiconductor materials can cause crystal rearrangement and recrystallization during annealing to form grains with ordered arrangement. Therefore, in the embodiments of the present disclosure, according to actual process requirements, the material of the second pattern layer (the semiconductor film) is selected as crystalline oxide, or amorphous oxide. In a case where the amorphous oxide is selected, the material of the second pattern layer needs to be selected so that it may complete crystallization during annealing.

S300, depositing a conductive material thin film, and patterning the conductive material thin film to form a first gate electrode. The second film layer is formed between the first film layer and the first gate electrode.

In this preparation method, the oxygen element is supplemented into the second film layer (the second pattern layer) through annealing. Therefore, the second film layer does not need to be prepared in a high-oxygen environment (for example, a high oxygen partial pressure). This approach not only prevents the channel of the thin film transistor from remaining conductive due to insufficient oxygen content in the second film layer but also avoids etching residues caused by excessive oxygen content, which would otherwise make the second film layer difficult to etch during the etching process.

For example, in at least one embodiment of the present disclosure, the above step S100 may include: depositing a first amorphous oxide film, and patterning the first amorphous oxide film to obtain the first pattern layer. That is, the material of the first pattern layer used to form the first film layer is semiconductor material (amorphous oxide). Under this design, the specific materials of the first film layer and the second film layer as well as the formation environment can refer to the relevant descriptions in the aforementioned embodiments, and will not be repeated here.

For example, in some embodiments of the present disclosure, when performing the aforementioned step S100, the provided conditions are: depositing the first amorphous oxide film in an environment with a first oxygen partial pressure, and depositing the semiconductor film in an environment with a second oxygen partial pressure, where the first oxygen partial pressure is greater than the second oxygen partial pressure.

For example, the first oxygen partial pressure is 30% to 90%, and the second oxygen partial pressure is 10% to 60%.

For example, in some embodiments of the present disclosure, the step of forming the first pattern layer including oxygen element on the base substrate may include: depositing an oxygen-rich oxide film layer, and patterning the first amorphous oxide film to obtain the first pattern layer. For the relevant explanations regarding the formation of the first film layer from the oxygen-rich oxide film layer through annealing, please refer to the relevant descriptions in the aforementioned embodiments, and it will not be repeated here.

For example, in at least one embodiment of the present disclosure, the preparation method may also include: depositing a second amorphous oxide film, and patterning the second amorphous oxide film to obtain a third pattern layer, where the first pattern layer, the second pattern layer, and the third pattern layer are stacked on the base substrate, the second pattern layer is located between the first pattern layer and the third pattern layer, and the second pattern layer is in contact with the third pattern layer; in process of performing annealing on the first pattern layer and the second pattern layer, synchronously performing annealing on the third pattern layer so that the third pattern layer forms a third film layer. Under this design, the specific material and formation environment of the third film layer may be referred to the relevant descriptions in the aforementioned embodiments, and will not be repeated here.

For example, the second amorphous oxide film may be deposited in an environment with a third oxygen partial pressure, and the first oxygen partial pressure is greater than the third oxygen partial pressure, and the third oxygen partial pressure is greater than the second oxygen partial pressure. For example, the third oxygen partial pressure is 15% to 85%.

In at least one embodiment of the present disclosure, the preparation method may also include: depositing a conductive material thin film on the base substrate, and patterning the conductive material thin film to form a second gate electrode, where the second gate electrode is formed on a side of the active layer away from the first gate electrode. For the structure of the thin film transistor when it is formed as a dual-gate thin film transistor, please refer to the relevant descriptions in the aforementioned embodiments, and it will not be repeated here.

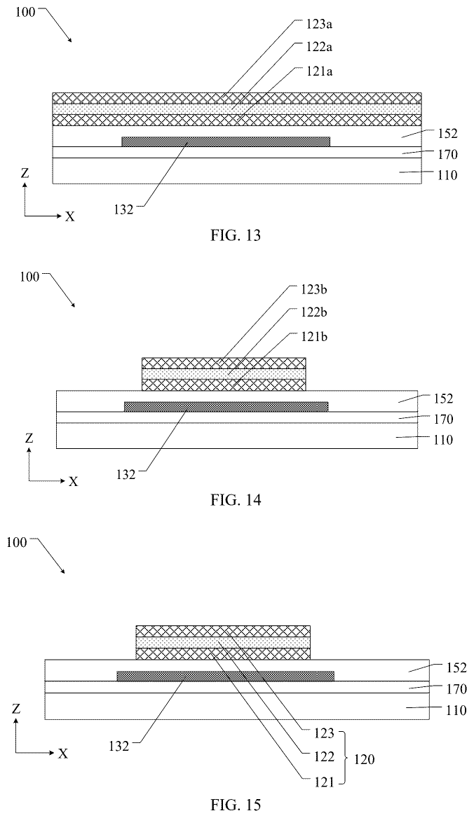

Hereinafter, taking the fabrication of the thin film transistor shown in FIG. 7 as an example, the process of the preparation method of the thin film transistor according to at least one embodiment of the present disclosure will be described, specifically referring to the process steps shown in FIGS. 12 to 17.

As shown in FIG. 12, a base substrate 110 is provided and an insulating material film layer and a conductive material thin film are sequentially deposited on the base substrate 110, where the insulating material film layer forms a buffer layer 170; the conductive material thin film is subjected to a patterning process to form a second gate electrode 132.

In the embodiments of the present disclosure, the patterning process may be a photolithography patterning process, for example, it may include: coating a photoresist on a structural layer to be patterned, exposing the photoresist using a mask plate, developing the exposed photoresist to obtain a photoresist pattern, etching the structural layer (optionally via wet etching or dry etching) using the photoresist pattern, and then optionally removing the photoresist pattern. It should be noted that when the material of the structural layer includes photoresist, the required pattern may be formed by exposing the structural layer directly through the mask plate.

As shown in FIGS. 12 to 13, the insulating material film layer is deposited on the base substrate 110 with the second gate electrode 132 formed to form a second gate insulator layer 152. Then, a first amorphous oxide film 121a, a semiconductor film 122a, and a second amorphous oxide film 123a are sequentially deposited on the second gate insulator layer 152. The first amorphous oxide film 121a, the semiconductor film 122a, and the second amorphous oxide film 123a are formed in environments with oxygen partial pressures of 30% to 90%, 10% to 60%, and 15% to 85%, respectively.

As shown in FIGS. 13 to 14, the first amorphous oxide film 121a, the semiconductor film 122a, and the second amorphous oxide film 123a are subjected to a patterning process to form a first pattern layer 121b, a second pattern layer 122b, and a third pattern layer 123b, respectively.

As shown in FIGS. 14 to 15, annealing is performed on the first pattern layer 121b, the second pattern layer 122b, and the third pattern layer 123b to form a first film layer 121, a second film layer 122, and a third film layer 123, respectively, where the first film layer 121, the second film layer 122, and the third film layer 123 stacked together constitute an active layer 120.

For example, in the step shown in FIG. 15, a doping process may be performed to conductorize both ends of the second film layer 122.

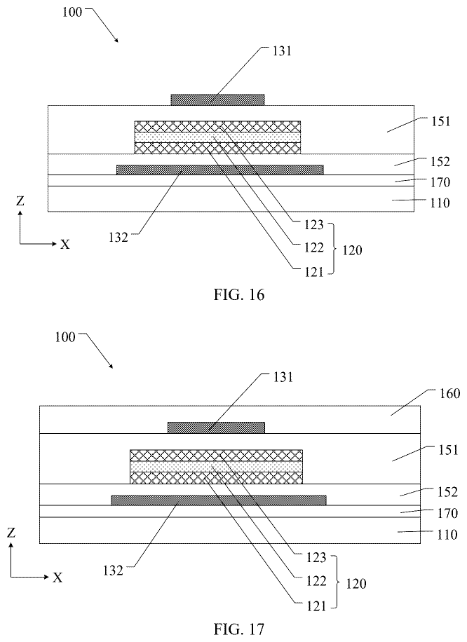

As shown in FIGS. 15 to 16, an insulating material is deposited on the active layer 120 to form a first gate insulator layer 151; then the conductive material thin film is deposited on the first gate insulator layer 151, and the conductive material thin film is subjected to a patterning process to form a first gate electrode 131.

As shown in FIGS. 16 to 17, the insulating material film is deposited on the base substrate 110 with the first gate electrode 131 formed thereon to form an interlayer dielectric layer 160.

As shown in FIG. 17 and FIG. 7, the interlayer dielectric layer 160 is subjected to a patterning process to form via holes; the conductive material thin film is deposited on the interlayer dielectric layer 160, and the conductive material film is subjected to a patterning process to form a source electrode 141 and a drain electrode 142, where the source electrode 141 and the drain electrode 142 are connected to the active layer 120 through the via holes in the interlayer dielectric layer 160.

What is claimed is:

1. A thin film transistor, comprising a base substrate, an active layer and a first gate electrode, wherein the active layer and the first gate electrode are located on the base substrate, the active layer comprises a first film layer and a second film layer stacked on the base substrate, and the second film layer is located between the first film layer and the first gate electrode, and
the first film layer comprises oxygen element, and the second film layer comprises crystalline oxide.

2. The thin film transistor according to claim 1, wherein the first film layer is a semiconductor layer, and the first film layer is an amorphous oxide layer, and
the second film layer is located between the first film layer and the base substrate, or the first film layer is located between the second film layer and the base substrate.

3. The thin film transistor according to claim 2, wherein,
an orthographic projection, located on the base substrate, of the first film layer coincides with an orthographic projection, located on the base substrate, of the second film layer.

4. The thin film transistor according to claim 2, wherein,
material of the first film layer comprises at least one of In, Ga, or Zn; or
material of the second film layer comprises at least one of In, Sn, Ga, or Zn.

5. The thin film transistor according to claim 4, wherein,
the first film layer is doped with at least one of Fe, Cu, Al, Zr, or Ti; or
the second film layer is doped with at least one of Fe, Cu, Al, Zr, or Ti.

6. The thin film transistor according to claim 5, wherein the first film layer is configured as a base material layer comprising oxygen ion, the base material layer covers the base substrate, and at least a partial region of the base material layer comprises the oxygen ion,
an orthographic projection, located on the base substrate, of the second film layer at least partially overlaps with an orthographic projection, located on the base substrate, of the region comprising the oxygen ion in the base material layer, and
entire region of the base material layer comprises the oxygen ion, or a region, coinciding with the second film layer, of the base material layer comprises the oxygen ion, and a portion of the base material layer comprising the oxygen ion is the first film layer.

7. The thin film transistor according to claim 6, wherein,
the first film layer is located between the second film layer and the base substrate, and the base material layer is an inorganic layer.

8. The thin film transistor according to claim 7, wherein the active layer further comprises:
a third film layer, located between the second film layer and the first gate electrode, wherein the third film layer is an amorphous oxide film layer.

9. The thin film transistor according to claim 8, wherein an orthographic projection, located on the base substrate, of the third film layer coincides with an orthographic projection, located on the base substrate, of the second film layer.

10. The thin film transistor according to claim 8, wherein material of the third film layer comprises at least one of In, Ga, or Zn.

11. The thin film transistor according to claim 10, wherein material of the third film layer is doped with at least one of Fe, Cu, Al, Zr, or Ti.

12. The thin film transistor according to claim 1, further comprising a second gate electrode, wherein the second gate electrode is located on a side, away from the first gate electrode, of the active layer.

13. A display panel, comprising the thin film transistor according to claim 1.

14. A preparation method of a thin film transistor, comprising:
providing a base substrate;
forming a first pattern layer comprising oxygen element on the base substrate, depositing a semiconductor film on the base substrate, and patterning the semiconductor film to form a second pattern layer, wherein the first pattern layer and the second pattern layer are stacked on the base substrate and in contact with each other;
performing annealing on the first pattern layer and the second pattern layer, so that the oxygen element in the first pattern layer diffuses into the second pattern layer, wherein the first pattern layer after annealing forms a first film layer, the second pattern layer after annealing forms a second film layer, the second film layer comprises crystalline oxide, and the first film layer and the second film layer are used to form an active layer; and
depositing a conductive material thin film, and patterning the conductive material thin film to form a first gate electrode, wherein the second film layer is formed between the first film layer and the first gate electrode.

15. The preparation method according to claim 14, wherein the forming a first pattern layer comprising oxygen element on the base substrate comprises:
depositing a first amorphous oxide film, and patterning the first amorphous oxide film to obtain the first pattern layer;
wherein the first amorphous oxide film is deposited in an environment with a first oxygen partial pressure, the semiconductor film is deposited in an environment with a second oxygen partial pressure, and the first oxygen partial pressure is greater than the second oxygen partial pressure.

16. The preparation method according to claim 15, wherein the first oxygen partial pressure is 30% to 90%, and the second oxygen partial pressure is 10% to 60%.

17. The preparation method according to claim 16, further comprising:
depositing a second amorphous oxide film, and patterning the second amorphous oxide film to obtain a third pattern layer, wherein the first pattern layer, the second pattern layer and the third pattern layer are stacked on the base substrate, the second pattern layer is located between the first pattern layer and the third pattern layer, and the second pattern layer is in contact with the third pattern layer; and
in process of performing annealing on the first pattern layer and the second pattern layer, synchronously performing annealing on the third pattern layer so that the third pattern layer forms third film layer, wherein the third film layer is used to form the active layer;
wherein the second amorphous oxide film is deposited in an environment with a third oxygen partial pressure, and the first oxygen partial pressure is greater than the third oxygen partial pressure, and the third oxygen partial pressure is greater than the second oxygen partial pressure.

18. The preparation method according to claim 17, wherein the third oxygen partial pressure is 15% to 85%.

19. The preparation method according to claim 14, wherein the forming a first pattern layer comprising oxygen element on the base substrate comprises:
depositing an oxygen-rich oxide film layer, and patterning the first amorphous oxide thin film to obtain the first pattern layer;
wherein the second film layer is formed between the first film layer and the base substrate; or the first film layer is formed between the second film layer and the base substrate, and an orthographic projection, located on the base substrate, of the second film layer is located within an orthographic projection, located on the base substrate, of the first film layer.

20. The preparation method according to claim 14, further comprising:
depositing a conductive material thin film, and patterning the conductive material thin film to form a second gate electrode;
wherein the second gate electrode is formed on a side of the active layer away from the first gate electrode.
